(19) United States
(12) Patent Application Publication
(10) Pub. No.: US 2026/0075751 A1
(43) Pub. Date: Mar. 12, 2026

(54) SYSTEMS AND METHODS FOR DETECTING DEBRIS IN AIR MOVERS

(71) Applicant: Dell Products L.P., Round Rock, TX (US)

(72) Inventors: Ihab SAAD, Austin, TX (US); Qinghong HE, Austin, TX (US)

(73) Assignee: Dell Products L.P., Round Rock, TX (US)

(21) Appl. No.: 18/882,320

(22) Filed: Sep. 11, 2024

(51) Int. Cl. H05K 7/20

(52) U.S. Cl. CPC H05K 7/20209; H05K 7/2019

(57) ABSTRACT

An information handling system may include an air mover array comprising one or more air movers, a debris detection system comprising an emitter configured to emit electromagnetic energy and a detector configured to detect an intensity of the electromagnetic energy incident at the detector and communicate a signal indicative of the intensity, and logic configured to receive the signal, compare the intensity indicated by the signal to a threshold level, and perform a remedial action if the intensity is below the threshold level.

### TECHNICAL FIELD

The present disclosure relates in general to information handling systems, and more particularly to cooling of information handling system components using one or more air movers, including detecting debris in an air mover.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As processors, graphics cards, random access memory (RAM) and other components in information handling systems have increased in clock speed and power consumption, the amount of heat produced by such components as a side-effect of normal operation has also increased. Often, the temperatures of these components need to be kept within a reasonable range to prevent overheating, instability, malfunction and damage leading to a shortened component lifespan. Accordingly, air movers (e.g., cooling fans and blowers) have often been used in information handling systems to cool information handling systems and their components.

In information handling systems, debris (e.g., dust) carried by circulated air may accumulate near or within air movers. Such accumulation of debris may lead to reduced heat dissipation capacity, which in turn may lead to the information handling system running at a higher temperature, at reduced performance, and/or at a higher acoustic level, which may negatively affect user experience.

### SUMMARY

In accordance with the teachings of the present disclosure, the disadvantages and problems associated with debris accumulation in an information handling may be substantially reduced or eliminated.

In accordance with embodiments of the present disclosure, an information handling system may include an air mover array comprising one or more air movers, a debris detection system comprising an emitter configured to emit electromagnetic energy and a detector configured to detect an intensity of the electromagnetic energy incident at the detector and communicate a signal indicative of the intensity, and logic configured to receive the signal, compare the intensity indicated by the signal to a threshold level, and perform a remedial action if the intensity is below the threshold level.

In accordance with these and other embodiments of the present disclosure, a method may include emitting electromagnetic energy from an emitter of a debris detection system located proximate to one or more airflow exhausts of one or more air movers, detecting an intensity of the electromagnetic energy incident at a detector and communicating a signal indicative of the intensity, comparing the intensity indicated by the signal to a threshold level, and performing a remedial action if the intensity is below the threshold level.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of selected components of an example information handling system, in accordance with embodiments of the present disclosure;

FIG. 2 illustrates an isometric perspective view of selected components within an interior of an example information handling system, in accordance with embodiments of the present disclosure;

FIG. 3 illustrates an isometric perspective view of selected components within an interior of another example information handling system, in accordance with embodiments of the present disclosure; and

FIG. 4 illustrates an isometric perspective view of selected components of an example air mover, in accordance with embodiments of the present disclosure.

### DETAILED DESCRIPTION

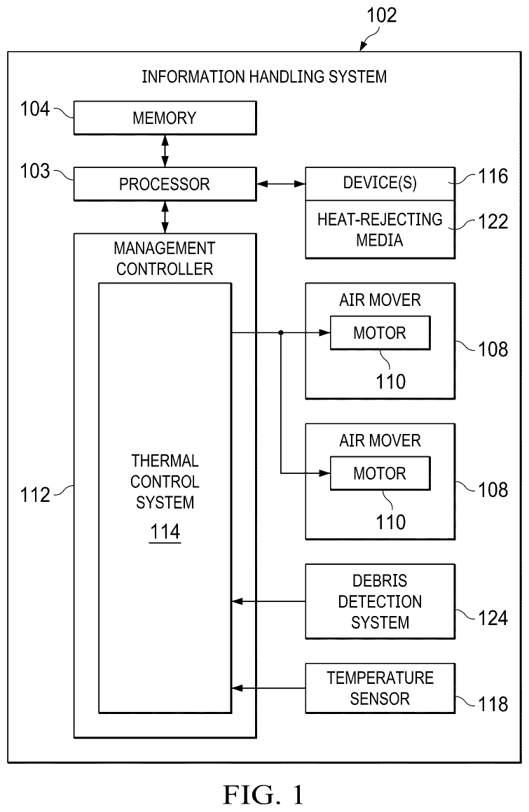

Preferred embodiments and their advantages are best understood by reference to FIGS. 1 through 4, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages; electro-mechanical devices (e.g., air movers), displays, and power supplies.

FIG. 1 illustrates a block diagram of selected components of an example information handling system 102, in accordance with embodiments of the present disclosure. In some embodiments, information handling system 102 may comprise a server chassis configured to house a plurality of servers or “blades. ” In other embodiments, information handling system 102 may comprise a personal computer (e.g., a desktop computer, laptop computer, mobile computer, and/or notebook computer). In yet other embodiments, information handling system 102 may comprise a storage enclosure configured to house a plurality of physical disk drives and/or other computer-readable media for storing data. As shown in FIG. 1, information handling system 102 may comprise a processor 103, a memory 104 communicatively coupled to processor 103, a plurality of air movers 108, a management controller 112, one or more devices 116 communicatively coupled to processor 103, a temperature sensor 118, heat-rejecting media 122 thermally coupled to device(s) 116, and a debris detection system 124.

Processor 103 may comprise any system, device, or apparatus operable to interpret and/or execute program instructions and/or process data, and may include, without limitation a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to processor 103 and may comprise any system, device, or apparatus operable to retain program instructions or data for a period of time. Memory 104 may comprise random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to information handling system 102 is turned off.

An air mover 108 may include any mechanical or electro-mechanical system, apparatus, or device operable to move air and/or other gases in order to cool information handling resources of information handling system 102. In some embodiments, an air mover 108 may comprise a fan (e.g., a rotating arrangement of vanes or blades which act on the air). In other embodiments, an air mover 108 may comprise a blower (e.g., a centrifugal fan that employs rotating impellers to accelerate air received at its intake and change the direction of the airflow). In these and other embodiments, rotating and other moving components of an air mover 108 may be driven by a motor 110. The rotational speed of motor 110 may be controlled by an air mover control signal (e.g., a pulse-width modulation signal) communicated from thermal control system 114 of management controller 112. In operation, an air mover 108 may cool information handling resources of information handling system 102 by drawing cool air into an enclosure housing the information handling resources from outside the chassis, expelling warm air from inside the enclosure to the outside of such enclosure, and/or moving air across one or more heat sinks (not explicitly shown) internal to the enclosure to cool one or more information handling resources.

Management controller 112 may comprise any system, device, or apparatus configured to facilitate management and/or control of information handling system 102 and/or one or more of its component information handling resources. Management controller 112 may be configured to issue commands and/or other signals to manage and/or control information handling system 102 and/or its information handling resources. Management controller 112 may comprise a microprocessor, microcontroller, DSP, ASIC, field programmable gate array (“FPGA”), EEPROM, or any combination thereof. Management controller 112 also may be configured to provide out-of-band management facilities for management of information handling system 102. Such management may be made by management controller 112 even if information handling system 102 is powered off or powered to a standby state. In certain embodiments, management controller 112 may include or may be an integral part of a baseboard management controller (BMC), a remote access controller (e.g., a Dell Remote Access Controller or Integrated Dell Remote Access Controller), or an enclosure controller. In other embodiments, management controller 112 may include or may be an integral part of a chassis management controller (CMC).

As shown in FIG. 1, management controller 112 may include a thermal control system 114. Thermal control system 114 may include any system, device, or apparatus configured to receive one or more signals indicative of one or more temperatures within information handling system 102 (e.g., one or more signals from one or more temperature sensors 118) and based on such one or more signals, calculate an air mover driving signal (e.g., a pulse-width modulation signal) to maintain an appropriate level of cooling, increase cooling, or decrease cooling, as appropriate, and communicate such air mover driving signal to air movers 108. Thermal control for air mover 108 by thermal control system 114 may be performed in any suitable manner, for example, as described in U.S. Pat. No. 10,146,190 entitled “Systems and Methods for Providing Controller Response Stability in a Closed-Loop System.”

In addition, thermal control system 114 may also be configured to maintain acoustic limits and/or maintain acoustic preferences for sound generated by air movers 108, for example, as described in U.S. patent application Ser. No. 16/852,118, filed Apr. 17, 2020, and entitled “Systems and Methods for Acoustic Limits of Thermal Control System in an Information Handling System,” which is incorporated by reference herein in its entirety.

In some embodiments, thermal control system 114 may include a program of instructions (e.g., software, firmware) configured to, when executed by a processor or controller integral to management controller 112, carry out the functionality of thermal control system 114.

A device 116 may comprise any component information handling system of information handling system 102, including without limitation processors, buses, memories, I/O devices and/or interfaces, storage resources, network interfaces, motherboards, integrated circuit packages; electro-mechanical devices, displays, and power supplies.

Temperature sensor 118 may comprise any system, device, or apparatus (e.g., a thermometer, thermistor, etc.) configured to communicate a signal to thermal control system 114 indicative of a temperature within information handling system 102.

Heat-rejecting media 122 may include any system, device, or apparatus configured to transfer heat from an information handling resource (e.g., device(s) 116, as shown in FIG. 1), thus reducing a temperature of the information handling resource. For example, heat-rejecting media 122 may include one or more solids thermally coupled to the information handling resource (e.g., heat pipe, heat spreader, heatsink, finstack, etc.) such that heat generated by the information handling resource is transferred from the information handling resource. Further, heat-rejecting media 122 may be arranged to be located within the airflow path of airflow generated by air movers 108, such that heat transferred to heat-rejecting media 122 from device 116 may further be transferred to such airflow. Although, for purposes of clarity and exposition, heat-rejecting media 122 is shown as being thermally coupled to device(s) 116, it is understood that heat-rejecting media 122 may also be thermally coupled to other information handling resources (e.g., processor 103 and/or memory 104) of information handling system 102 in addition to or in lieu of being thermally coupled to device 116.

Debris detection system 124 may be communicatively coupled to thermal control system 114, and may comprise any suitable system, device, or apparatus configured to optically detect for the presence of debris (e.g., dust particles) within or near air movers 108. Example implementations for debris detection system 124 are set forth in greater detail below.

In addition to processor 103, memory 104, air mover 108, management controller 112, device(s) 116, temperature sensor 118, heat-rejecting media 122, and debris detection system 124, information handling system 102 may include one or more other information handling resources. In addition, for the sake of clarity and exposition of the present disclosure, FIG. 1 depicts two air movers 108 and one temperature sensor 118. In embodiments of the present disclosure, information handling system 102 may include any number of air movers 108 and temperature sensors 118.

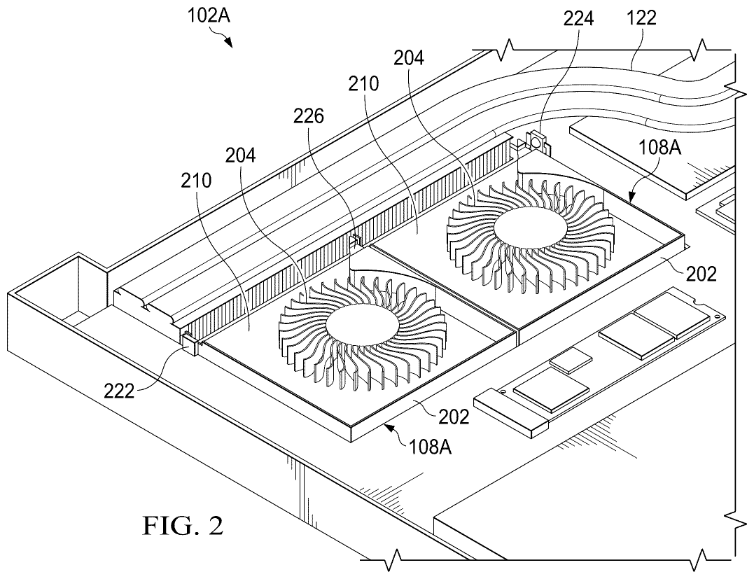

FIG. 2 illustrates an isometric perspective view of selected components within an interior of an example information handling system 102A, in accordance with embodiments of the present disclosure. In some embodiments, information handling system 102A may implement information handling system 102, and may include some or all of the components described above with respect to FIG. 1.

As shown in FIG. 2, information handling system 102A may include air movers 108A, which may implement air movers 108 of FIG. 1. Each air mover 108A may comprise a housing 202 and an impeller 204 located substantially within housing 202. For purposes of clarity and exposition, a bottom cover of housing 202 is removed. Housing 202 may include an inlet which may be formed within the bottom cover of housing 202 and an exhaust 210 formed in a side of housing 202. Impeller 204 may be rotationally coupled to housing 202 about an axis, and may include a plurality of fins. In operation, a motor (e.g., motor 110 shown in FIG. 1) may cause impeller 204 to rotate about its axis relative to housing 202, causing air to be drawn into housing 202 via the inlet and expelled from housing 202 via exhaust 210 in order to drive airflow through or proximate to heat-rejecting media 122.

As also shown in FIG. 2, information handling system 102A may also include an emitter 222 of electromagnetic energy (e.g., visible light or non-visible electromagnetic energy) and a detector 224 of electromagnetic energy which may be used to implement debris detection system 124 of FIG. 1.

Emitter 222 may comprise any suitable system, device, or apparatus configured to emit electromagnetic energy, such as a laser or light-emitting diode, for example, configured to emit electromagnetic energy of any suitable wavelength or wavelengths. In some embodiments, such wavelength or wavelengths may be in the range of electromagnetic energy as substantially absorbed or reflected by solid matter, such as within the visible spectrum or near-visible (e.g., infrared, ultraviolet) spectrums.

Detector 224 may comprise any suitable system, device, or apparatus configured to detect electromagnetic energy at the wavelength or wavelengths emitted by emitter 222.

In operation, emitter 222 may emit electromagnetic energy, with at least some of such electromagnetic energy emitted in the direction of detector 224. Detector 224 may then detect an intensity of electromagnetic energy received at detector 224, and communicate a signal to thermal control system 114 indicative of such intensity. In response, thermal control system 114 may compare the measured intensity to a threshold value, with a measured intensity below the threshold value being indicative of solid debris (e.g., dust) present between emitter 222 and detector 224. If the measured intensity is below the threshold value, thermal control system 114 may take a remedial action, such as issuing an alert or warning to an administrator, technician, or other user of information handling system 102A.

As shown in FIG. 2, emitter 222 and detector 224 may be located proximate to exhausts 210, and thus may be configured to detect presence of debris at exhausts 210 and/or the presence of debris between exhausts 210 and heat-rejecting media 122.

As also shown in FIG. 2, a channel 226 may be present between emitter 222 and detector 224. In some embodiments, such channel 226 may exist in a region of space between exhausts 210 and heat-rejecting media 122, in which case one or both of emitter 222 and detector 224 may be located between air movers 108A and heat-rejecting media 122. In other embodiments, such channel 226 may be formed within housings 202 of one or both of air movers 108A, in which case one or both of emitter 222 and detector 224 may be located within housings 202 and integral to one or both air movers 108A.

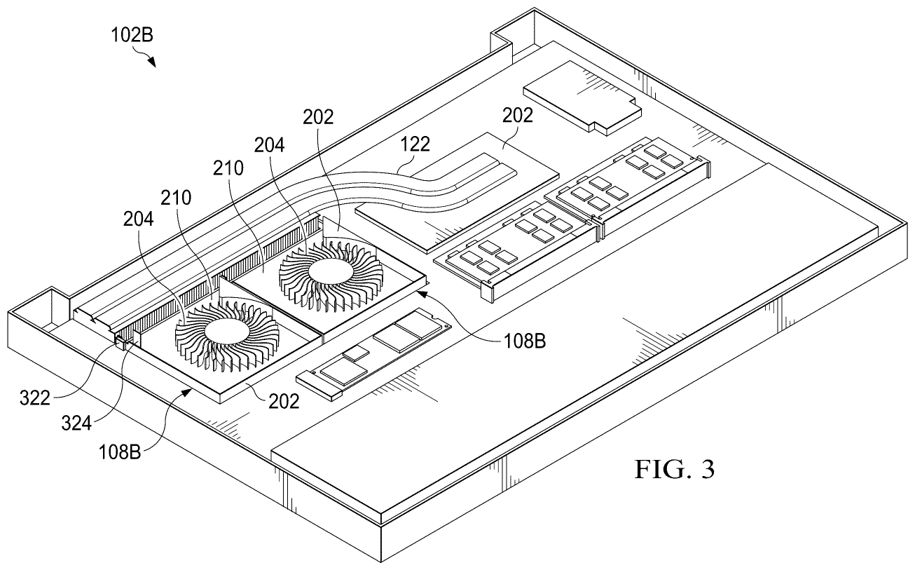

FIG. 3 illustrates an isometric perspective view of selected components within an interior of an example information handling system 102B, in accordance with embodiments of the present disclosure. In some embodiments, information handling system 102B may implement information handling system 102, and may include some or all of the components described above with respect to FIG. 1. Further, information handling system 102B may be similar in many respects to information handling system 102A, and thus only certain differences between information handling system 102A and information handling system 102B may be described below.

As shown in FIG. 3, information handling system 102A may include air movers 108B, which may implement air movers 108 of FIG. 1. Each air mover 108B may comprise a housing 202 and an impeller 204 located substantially within housing 202. For purposes of clarity and exposition, a bottom cover of housing 202 is removed. Housing 202 may include an inlet which may be formed within the bottom cover of housing 202 and an exhaust 210 formed in a side of housing 202. Impeller 204 may be rotationally coupled to housing 202 about an axis, and may include a plurality of fins. In operation, a motor (e.g., motor 110 shown in FIG. 1) may cause impeller 204 to rotate about its axis relative to housing 202, causing air to be drawn into housing 202 via the inlet and expelled from housing 202 via exhaust 210 in order to drive airflow through or proximate to heat-rejecting media 122.

As also shown in FIG. 3, information handling system 102B may also include a combination emitter/detector 322. Emitter/detector 322 may include both an emitter of electromagnetic energy (e.g., visible light or non-visible electromagnetic energy) and a detector of electromagnetic energy. Information handling system 102B may also include a reflector 324. Together, emitter/detector 322 and reflector 324 may implement debris detection system 124 of FIG. 1.

The emitter of emitter/detector 322 may comprise any suitable system, device, or apparatus configured to emit electromagnetic energy, such as a laser or light-emitting diode, for example, configured to emit electromagnetic energy of any suitable wavelength or wavelengths. In some embodiments, such wavelength or wavelengths may be in the range of electromagnetic energy as substantially absorbed or reflected by solid matter, such as within the visible spectrum or near-visible (e.g., infrared, ultraviolet) spectrums. The detector of emitter/detector 322 may comprise any suitable system, device, or apparatus configured to detect electromagnetic energy at the wavelength or wavelengths emitted by its emitter.

Reflector 324 may comprise a mirror, reflective tape, or other reflective surface configured to reflect electromagnetic energy emitted by emitter/detector 322 back towards emitter/detector 322.

In operation, emitter/detector 322 may emit electromagnetic energy, with at least some of such electromagnetic energy emitted in the direction of reflector 324. Reflector 324 may then reflect some or all of the electromagnetic energy incident upon it back towards emitter/detector 322. Emitter/detector 322 may detect an intensity of electromagnetic energy reflected back from reflector 324, and communicate a signal to thermal control system 114 indicative of such intensity. In response, thermal control system 114 may compare the measured intensity to a threshold value, with a measured intensity below the threshold value being indicative of solid debris (e.g., dust) present between emitter/detector 322 and reflector 324. If the measured intensity is below the threshold value, thermal control system 114 may take a remedial action, such as issuing an alert or warning to an administrator, technician, or other user of information handling system 102B.

As shown in FIG. 3, emitter/detector 322 and reflector 324 may be located proximate to exhausts 210, and thus may be configured to detect presence of debris at exhausts 210 and/or the presence of debris between exhausts 210 and heat-rejecting media 122. In some embodiments, one or both of emitter/detector 322 and reflector 324 may be located between air movers 108B and heat-rejecting media 122. In other embodiments, one or both of emitter/detector 322 and reflector 324 may be located within housings 202 and integral to one or both air movers 108B.

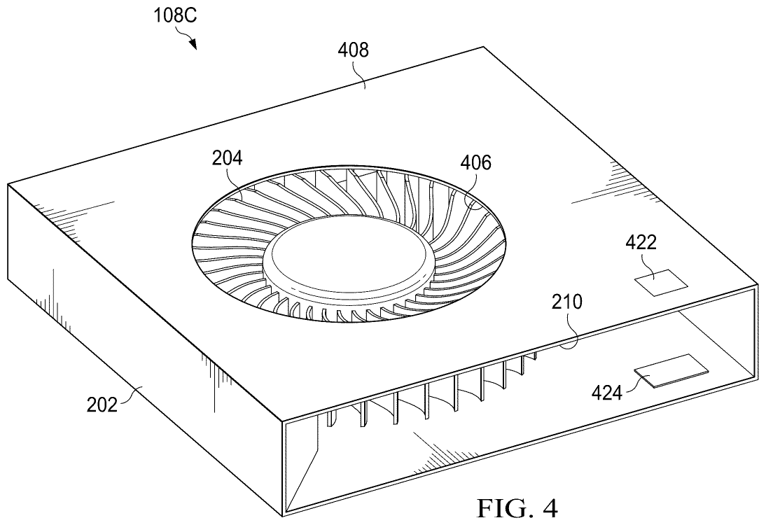

FIG. 4 illustrates an isometric perspective view of selected components or an example air mover 108C, in accordance with embodiments of the present disclosure. Air mover 108C may be used to implement one or more air movers 108 of FIG. 1.

Air mover 108C may comprise a housing 202 and an impeller 204 located substantially within housing 202. Housing 202 may include an inlet 406 which may be formed within a bottom cover 408 of housing 202 and an exhaust 210 formed in a side of housing 202. Impeller 204 may be rotationally coupled to housing 202 about an axis, and may include a plurality of fins. In operation, a motor (e.g., motor 110 shown in FIG. 1) may cause impeller 204 to rotate about its axis relative to housing 202, causing air to be drawn into housing 202 via inlet 406 and expelled from housing 202 via exhaust 210 in order to drive airflow through or proximate to heat-rejecting media 122.

As also shown in FIG. 4, air mover 108C may also include a combination emitter/detector 422 housed within housing 402. Emitter/detector 422 may include both an emitter of electromagnetic energy (e.g., visible light or non-visible electromagnetic energy) and a detector of electromagnetic energy. Air mover 108C may also include a reflector 424 housed within housing 202. Together, emitter/detector 422 and reflector 424 may implement debris detection system 124 of FIG. 1.

The emitter of emitter/detector 422 may comprise any suitable system, device, or apparatus configured to emit electromagnetic energy, such as a laser or light-emitting diode, for example, configured to emit electromagnetic energy of any suitable wavelength or wavelengths. In some embodiments, such wavelength or wavelengths may be in the range of electromagnetic energy as substantially absorbed or reflected by solid matter, such as within the visible spectrum or near-visible (e.g., infrared, ultraviolet) spectrums. The detector of emitter/detector 422 may comprise any suitable system, device, or apparatus configured to detect electromagnetic energy at the wavelength or wavelengths emitted by its emitter.

Reflector 424 may comprise a mirror, reflective tape, or other reflective surface configured to reflect electromagnetic energy emitted by emitter/detector 422 back towards emitter/detector 422.

In operation, emitter/detector 422 may emit electromagnetic energy, with at least some of such electromagnetic energy emitted in the direction of reflector 424. Reflector 424 may then reflect some or all of the electromagnetic energy incident upon it back towards emitter/detector 422. Emitter/detector 422 may detect an intensity of electromagnetic energy reflected back from reflector 424, and communicate a signal to thermal control system 114 indicative of such intensity. In response, thermal control system 114 may compare the measured intensity to a threshold value, with a measured intensity below the threshold value being indicative of solid debris (e.g., dust) present between emitter/detector 422 and reflector 424. If the measured intensity is below the threshold value, thermal control system 114 may take a remedial action, such as issuing an alert or warning to an administrator, technician, or other user of an information handling system 102 comprising air mover 108C.

As shown in FIG. 4, emitter/detector 422 and reflector 424 may be located proximate to exhaust 210, and thus may be configured to detect presence of debris at exhaust 210.

Although debris detection system 124 has been described herein as an electromagnetic sensor (e.g., using visible or near visible light), it is understood that other suitable sensors may be used provided a detector is sensitive to debris between such detector and an emitter. Non-limiting examples of such debris detection systems may be those that use radar, ultrasound, or any other suitable approach.

While the terms “top,” “bottom,” “front,” “back,” and “side” are used for purposes of exposition and clarity, such terms are not intended to limit any of the components disclosed herein to a particular orientation or configuration.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. §112(f) unless the words “means for” or “step for” are explicitly used in the particular claim.

What is claimed is:

1. An information handling system comprising:
an air mover array comprising one or more air movers;
a debris detection system comprising:
an emitter configured to emit electromagnetic energy; and
a detector configured to detect an intensity of the electromagnetic energy incident at the detector and communicate a signal indicative of the intensity; and
logic configured to receive the signal, compare the intensity indicated by the signal to a threshold level, and perform a remedial action if the intensity is below the threshold level.

2. The information handling system of claim 1, wherein the emitter and the detector are integral to a combined emitter/detector, and the debris detection system further comprises a reflector configured to reflect electromagnetic energy emitted by the combined emitter/detector back to the combined emitter/detector.

3. The information handling system of claim 2, wherein at least one of the combined emitter/detector and the reflector are integral to a single air mover of the air mover array.

4. The information handling system of claim 2, wherein at least one of the combined emitter/detector and the reflector are integral to the air mover array.

5. The information handling system of claim 1, wherein at least one of the emitter and the detector are integral to the air mover array.

6. The information handling system of claim 1, wherein the electromagnetic energy emitted by the emitter is in the human-visible spectrum.

7. The information handling system of claim 1, wherein the electromagnetic energy emitted by the emitter is in one of the infrared and ultraviolet spectrum.

8. The information handling system of claim 1, wherein the remedial action comprises communication of an alert.

9. The information handling system of claim 1, wherein the emitter and the detector are located proximate to one or more airflow exhausts of the air movers of the air mover array.

10. A method comprising:
emitting electromagnetic energy from an emitter of a debris detection system located proximate to one or more airflow exhausts of one or more air movers;
detecting an intensity of the electromagnetic energy incident at a detector and communicating a signal indicative of the intensity;
comparing the intensity indicated by the signal to a threshold level; and
performing a remedial action if the intensity is below the threshold level.

11. The method of claim 10, wherein the emitter and the detector are integral to a combined emitter/detector, and the method further comprises reflecting, from a reflector, electromagnetic energy emitted by the combined emitter/detector back to the combined emitter/detector.

12. The method of claim 11, wherein at least one of the combined emitter/detector and the reflector are integral to a single air mover of the one or more air movers.

13. The method of claim 11, wherein at least one of the combined emitter/detector and the reflector are integral to the one or more air movers.

14. The method of claim 10, wherein at least one of the emitter and the detector are integral to the one or more air movers.

15. The method of claim 10, wherein the electromagnetic energy emitted by the emitter is in the human-visible spectrum.

16. The method of claim 10, wherein the electromagnetic energy emitted by the emitter is in one of the infrared and ultraviolet spectrum.

17. The method of claim 10, wherein the remedial action comprises communication of an alert.
